(19) United States
(12) Patent Application Publication
(10) Pub. No.: US 2002/0157612 A1
(43) Pub. Date: Oct. 31, 2002

(54) Vacuum evaporation apparatus

(75) Inventors: Ying-Che Shih, Hsin-Chu City (TW); Pei-Liang Chiu, Taipei (TW)

Correspondence Address: Ladas & Parry, 26 West 61 Street, New York, NY, 10023, US

(73) Assignee: PRINCO CORP.

(21) Appl. No.: 10/119,632

(22) Filed: Apr. 10, 2002

(30) Foreign Application Priority Data
Apr. 11, 2001 (TW) 090108595

(51) Int. Cl. C23C 16/00

(52) U.S. Cl. 118/726; 118/723 VE; 118/721; 118/720

(57) ABSTRACT

The present invention discloses a vacuum evaporation apparatus comprising a vacuum pump, an evaporation chamber and a power supply. The evaporation chamber comprises a substrate, an evaporation source and an evaporation mask. The evaporation mask exhibits a coefficient of thermal expansion substantially equal to the substrate, and the evaporation mask has a pattern of metal tracks. Thus, the apparatus of the present invention also can be applied to form solder bumps on a large sized silicon wafer. Moreover, the position pattern of the mask is formed by an anisotropic etching process; the diameter of the pattern will not be influenced by the thickness of the mask. Therefore, the tendency of the solder bumps with the smaller size and the pitch are met.

### BACKGROUND OF THE INVENTION

1. Field of the Invention

The present invention relates to a vacuum evaporation apparatus, and more particularly, to a vacuum evaporation apparatus for forming solder bumps on a silicon wafer.

2. Description of the Prior Art

As rapidly increase of the transistors in an integrated circuit (IC), the requirements for an IC package are becoming stricter and stricter. At the present time, the most popular package technology of a high density IC is the flip chip package technology. The flip chip process, also called controlled collapse chip connection process (C4 process), was first developed by the IBM Corp. in 1960 to replace the conventional wire bonding technology. Generally, the flip chip technology forms a plurality of the solder bumps on I/O pads of an IC chip. Then, the chip is fliped to electrically contact with the circuit paths of a substrate.

The mask of the conventional C4 process is made with molybdenum. The process requirements are becoming stricter and stricter. This means that, the size and the pitch of the solder bumps are becoming smaller and smaller. Thus, a shift between the pattern of the molybdenum mask and the ideal position of the solder bumps on the silicon occurs, due to the mismatch of the coefficients of the thermal expansion (CTE) between the molybdenum mask and the silicon wafer.

FIG. 1 depicts a shifting diagram between the pattern of the molybdenum mask and the ideal position of the solder bumps on a wafer formed by the conventional C4 process. In FIG. 1, a solid line 11 indicates the size of the silicon wafer expanded at high temperature, and a dotted line 12 indicates the size of the molybdenum mask expanded at high temperature. Taking an 8-inch silicon wafer as an example, when the temperature of the evaporation chamber is between 150-200, the shift between the pattern of the molybdenum mask and the ideal position of the solder bumps on the 8-inch silicon wafer is more than 10 micrometers. Furthermore, the high temperature evaporated atom will also deposit on the mask, thus the temperature of the molybdenum mask will be much higher than that of the silicon wafer. Therefore, the obvious shift between the molybdenum mask and the ideal position of the solder bumps on the silicon wafer occurs.

FIG. 2 depicts a conventional process for forming a molybdenum mask. A molybdenum substrate 21 is applied with a photo resist 22 on both sides and then proceeds a photolithography process to expose the pattern on the mask. After that, the molybdenum substrate 21, which is exposed by the photolithography process, is removed by a wet etching step and a pattern 23 is formed. Finally, the photo resist is removed and a molybdenum mask with a pattern of solder bumps is formed. Generally, the diameter of the pattern, which is formed with the process above-mentioned, is about ten microinch. However, the wet etching method is one of an isotropic etching method, thus the pattern radius etched by the wet etching method is larger than the thickness of the molybdenum substrate. In another word, the thickness of the molybdenum mask will become thinner and thinner, as the size of the solder bumps become smaller and smaller. Thus, the molybdenum mask is too thin to fix with the silicon wafer; or the center potion of the mask is hollow after fixing with the silicon wafer, and it causes the center portion of the pattern to be haloed after evaporation.

To overcome the shifting problem caused by the difference of the coefficients of the thermal expansion, U.S. Pat. No. 4,391,034 discloses a method for calculating and compensating the difference between the molybdenum mask and the silicon wafer at high temperature previously. In addition, U.S. Pat. No. 5,776,790 also discloses a method for controlling the evaporation rate by a thermal sensor apparatus to decrease the difference of the thermal expansion. However, the above-mentioned methods will complicate the process and increase the cost to adversely affect the market competitiveness.

### SUMMARY OF THE INVENTION

An object of the present invention is to provide a vacuum evaporation apparatus for forming solder bumps precisely on the correct positions of a wafer.

The second object of the present invention is to provide an evaporation mask having the same coefficient of thermal expansion as the silicon wafer, therefore the shift between the pattern of the evaporation mask and the position of the solder bumps on the silicon wafer is prevented in a high temperature process.

The third object of the present invention is to provide a process for forming an evaporation mask, in which the pattern is formed by an anisotropic etching method, thus the diameter of the pattern will not be influenced by the thickness of the mask.

In order to achieve the above objects and to avoid the disadvantages of the prior art, the present invention discloses a vacuum evaporation apparatus, which comprises a vacuum pump, an evaporation chamber and a power supply. The evaporation chamber comprises a substrate, an evaporation source and an evaporation mask. Metal tracks are disposed on the surface of the substrate. The evaporation mask exhibits a coefficient of thermal expansion substantially equal to the substrate, and the evaporation mask has a pattern of the metal tracks.

Since the coefficients of thermal expansion of the silicon mask and the silicon wafer are the same, the problem of a pattern shift on the evaporation mask is improved thereof.

In conclusion, to meet the light and small tendency for the future products, the substrate of the evaporation mask of the present invention can improve the quality of the evaporation and decreases the pitch and the size of the solder bumps.

### BRIEF DESCRIPTION OF THE DRAWINGS

FIG. 1 depicts a shifting diagram between the pattern of the molybdenum mask and the ideal position of the solder bumps formed by the conventional C4 process;

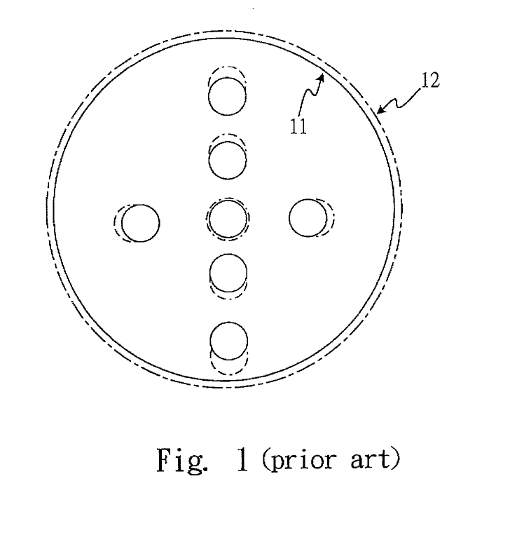

FIG. 2 depicts a process of forming a conventional molybdenum mask; and

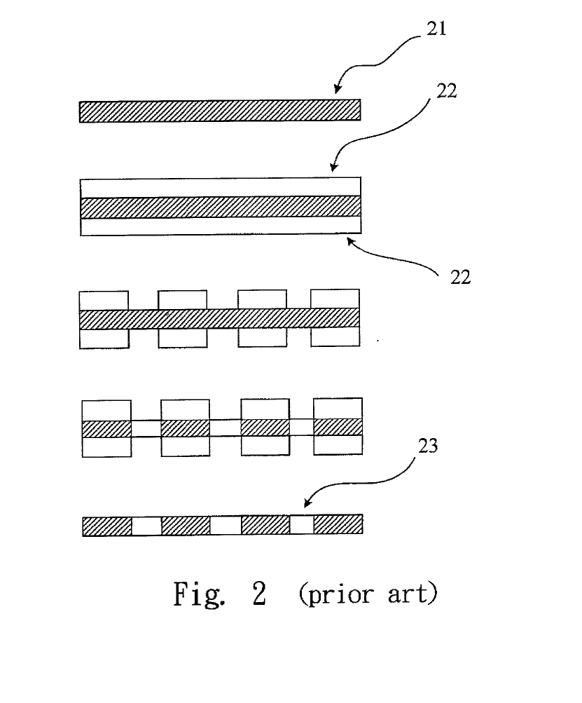

FIG. 3 depicts a vacuum evaporation apparatus of the present invention.

### DETAILED DESCRIPTION OF THE INVENTION

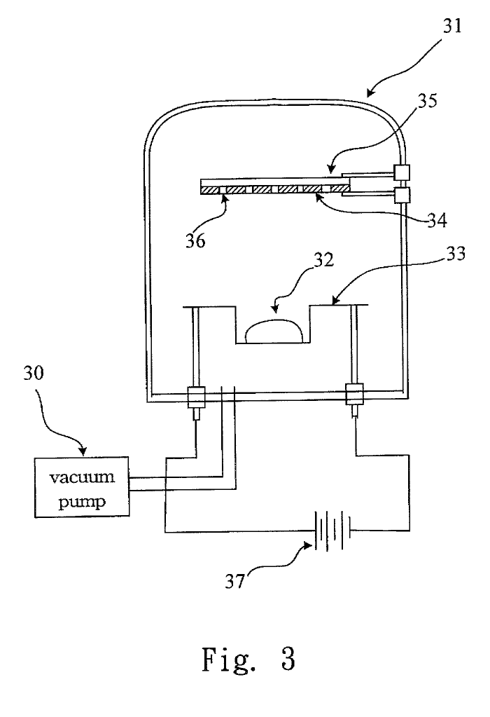

FIG. 3 depicts a vacuum evaporation apparatus of the present invention comprising a vacuum pump 30, an evaporation chamber 31 and a power supply 37. The evaporation chamber 31 comprises an evaporation mask 34, a silicon wafer 35, a crucible 33 and an evaporation source 32. The evaporation chamber 31 provides a vacuum environment to prevent the interference of atoms, which do not belong to the evaporation source. The crucible 33 is connected with the power supply 37 for heating the evaporation source 32 on the crucible 33 by the thermal energy produced by the resistance effect, inductance effect or an electron beam, etc. The evaporation source 32 will be evaporated at high temperature and the vapor of the evaporation source 32 will pass through the pattern of the mask 34 and deposit on the silicon wafer 35 and solder bumps will be formed. The mask 34 is fixed with the silicon wafer 35 and positioned between the evaporation source 32 and the silicon wafer 35. Generally, the material of the evaporation source 32 is a metal with low melting point, such as an alloy of tin and lead or aluminum etc. After heating the crucible 33, a vapor pressure of the evaporation source 32 is produced because of the thermal energy. The atoms evaporated from the evaporation source 32 will pass through the pattern of the mask 34 and deposit on the surface of the silicon wafer 35. Finally, the mask 34 is removed and solder bumps are formed.

In one preferred embodiment of the present invention, the substrate of the silicon mask 34 is a silicon wafer to prevent the disadvantages, such as the pattern shift caused by the difference of the coefficients of the thermal expansion between the silicon wafer and the mask and the haloing of the solder bumps because of the thinness of the mask 34. The pattern of the mask 34 of the present invention is formed by anisotropic etching methods comprising

1. laser drill the laser comprises carbon dioxide, Nd:YAG, eximer laser and copper vapor laser etc;

2. wet etching the process of the wet etching process comprises as follows:

(a) applying a photo resist on both sides of the silicon wafer and proceed with the photolithography process to expose the pattern of the mask;

(b) etching the silicon wafer, which is exposed by the photolithography process, with the alkali solution, such as potassium hydroxide solution;

(c) removing the residual photo resist such that the silicon mask with the position pattern of the solder bumps is formed;

3. dry etching could also be classified into the following two types

(1) reactive ion etching (RIE) applying a photo resist on the silicon wafer and proceeding with the photolithography process to expose the pattern of the mask; after that, placing the silicon wafer into a vacuum chamber and etching the silicon wafer, which is exposed by the photolithography process, with the plasma and the reactive gas (such as CF₄ and Ar); removing the residual photo resist such that the silicon mask with the position pattern of the solder bumps is formed;

(2) deep reactive ion etching (DRIE) the process of the deep reactive ion etching is similar to the reactive ion etching, however, the etcher being used in this process is different with the reactive ion etching, thus the anisotropic pattern produced by this process approximates to 90°.

The diameter of the solder bumps formed by the above-mentioned process is probably larger than 25 micrometer, and the pitch is probably larger than 75 micrometer. Moreover, the evaporation mask and wafer made by silicon is just an embodiment, and in practical application, the material of the evaporation mask and wafer used is not limited to silicon.

The methods and features of this invention have been sufficiently described in the above examples and descriptions. It should be understood that any modifications or changes without departing from the spirits of the invention are intended to be covered in the protection scopes of the invention.

What is claimed is:

1. A vacuum evaporation apparatus comprising a vacuum pump, an evaporation chamber and a power supply, characterized in that said evaporation chamber comprises:
(a) a substrate, whose surface is disposed by metal tracks;
(b) an evaporation source; and
(c) an evaporation mask exhibiting a coefficient of thermal expansion substantially equal to said substrate, and said evaporation mask having a pattern of said metal tracks;
whereby the coefficients of thermal expansion of said silicon mask and said silicon wafer are the same, a pattern shift on said evaporation mask is improved thereof.

2. The apparatus of claim 1, wherein said evaporation chamber further comprises a crucible connected to said power supply so as to heat said evaporation source by resistance effect.

3. The apparatus of claim 1, wherein said evaporation chamber further comprises a crucible connecting to said power supply so as to heat said evaporation source by inductance effect.

4. The apparatus of claim 1, wherein said evaporation chamber further comprises a crucible connecting to said power supply so as to heat said evaporation source by an electron beam.

5. The apparatus of claim 1, wherein said substrate is a silicon wafer, metal, organic or inorganic material.

6. The apparatus of claim 1, wherein said evaporation source is a metal, organic or inorganic material.

7. The apparatus of claim 1, wherein said pattern of said evaporation mask is formed by a laser-drilling process.

8. The apparatus of claim 7, wherein said laser is selected from a group consisting of carbon dioxide laser Nd:YAG eximer laser and copper vapor laser.

9. The apparatus of claim 1, wherein said pattern of said evaporation mask is formed by a wet etching process.

10. The apparatus of claim 1, wherein said pattern of said evaporation mask is formed by a dry etching process.

11. The apparatus of claim 10, wherein said dry etching process is a reactive ion etching process.

12. The apparatus of claim 10, wherein said dry etching process is a deep reactive ion etching process.
